(19) United States
(12) Patent Application Publication
(10) Pub. No.: US 2012/0103793 A1
(43) Pub. Date: May 3, 2012

(54) VACUUM FILM-FORMING APPARATUS AND POSITION DETECTION METHOD FOR SHUTTER PLATE OF VACUUM FILM-FORMING APPARATUS

(75) Inventor: Yoshinori Fujii, Susono-shi (JP)

(73) Assignee: ULVAC, INC., Chigasaki-shi (JP)

(21) Appl. No.: 13/379,410

(22) PCT Filed: Jun. 23, 2010
(86) PCT No.: PCT/JP2010/004181

§ 371 Date: Dec. 20, 2011

(30) Foreign Application Priority Data
Jun. 24, 2009 (JP) 2009-150263

(51) Int. Cl. C23C 14/34

(52) U.S. Cl. 204/192.1; 204/298.11

(57) ABSTRACT

At the time of detecting a position of a shutter plate, a laser light, for instance, is radiated from a detector (an optical sensor). The radiated laser light reaches the shutter plate through a window of a chamber. Then, the laser light is reflected by the surface of the shutter plate and re-enters the detector. The detector detects the time required from the emission of the laser light to the entry of the reflected light.

### TECHNICAL FIELD

The present invention relates to a vacuum film-forming apparatus and a position detection method for a shutter plate of the vacuum film-forming apparatus, specifically, to a technology that detects the displacement of the position where the shutter plate is held with high precision.

### BACKGROUND ART

For example, in a vacuum film-forming apparatus that forms a thin film on a film-forming target surface of a substrate, it is general for cleaning a target surface which is a film-forming material and/or stabilizing a film-forming property to perform a film-forming with respect to a dummy substrate (hereinafter, also referred to a shutter plate) (dummy sputtering) before a main process performing the film-forming (sputtering) with respect to a film-forming objective substrate (for example, refer to Patent Document 1).

When such dummy sputtering is executed, the sputtering is performed while placing the shutter plate on the stage where the film-forming target object is to be placed. When the shutter plate is to be placed on the stage, a shutter mechanism that has an arm which holds the shutter plate is operated to pivot the arm to a position overlapping with the stage. Then, the shutter plate is placed on the stage. Thus, since the stage is covered by the shutter plate, it is possible to prevent from performing the film-forming on the stage while performing the dummy sputtering.

### PRIOR ART DOCUMENT

### Patent Document

Patent Document 1: Japanese Unexamined Patent Application, First Publication No. 2003-158175

### SUMMARY OF INVENTION

### Problems to be Solved by the Invention

However, if the shutter plate is held by the arm in a state displaced from a preset holding reference position, there is a possibility that a part of the stage protrudes from the shutter plate and is exposed when the shutter plate has been placed on the stage. If a part of the stage protrudes from the shutter plate, there is a problem, for example, that the film-forming is performed in the exposed portion of the stage when performing the dummy sputtering and the thin film resulting from the film-forming scatters and becomes an impurity when performing the film-forming on the objective substrate.

The shutter plate is displaced from the reference position of holding the arm, for example, when the entire arm is tilted toward the forefront by the gravitational force and/or when the end portion of the shutter plate runs upon a definition member which is formed in the arm and defines the position where the shutter plate is held and the entire shutter plate inclines.

Aspects according to the present invention are intended to provide a vacuum film-forming apparatus that can accurately detect the positional displacement of the shutter plate used for the dummy sputtering and can place the shutter plate to the predetermined position on the stage.

In addition, the aspects according to the present invention are intended to provide a position detection method for the shutter plate of the vacuum film-forming apparatus that can accurately detect whether or not the shutter plate used for the dummy sputtering is in the holding reference position on the arm which is holding the shutter plate.

### Means for Solving the Problem

A vacuum film-forming apparatus according to an aspect of the present invention comprises: a chamber that maintains a vacuum of an inside thereof; a stage that is formed in the chamber and on which a shutter plate is placed; a target that is arranged so as to be opposed to the stage; a shutter mechanism that is formed so as to be capable of inserting into and evacuating from a space between the stage and the target and that has an arm which holds the shutter plate; and a detector that detects a displacement of the shutter plate held by the arm from a holding reference position.

The detector may be an optical sensor that detects a reflected light which is light irradiating toward the shutter plate and reflected by the shutter plate.

The detector may be an optical sensor that detects an intensity distribution of the reflected light with a solid-state image sensing device.

The detector is preferably arranged in an exterior of the chamber.

The detector may be arranged close to a guide pin which is formed in the arm and comes in contact with and supports the shutter plate.

The shutter plate preferably has two or more sites where the thicknesses thereof are different from each other.

A thickness of an outer edge portion of the shutter plate is preferably thicker than that of a center portion thereof.

A position detection method for a shutter plate of a vacuum film-forming apparatus according to an aspect of the present invention comprises: a chamber that maintains a vacuum of an inside thereof; a stage that is formed in the chamber and on which a shutter plate is placed; a target that is arranged so as to be opposed to the stage; a shutter mechanism that is formed so as to be capable of inserting into and evacuating from a space between the stage and the target and that has an arm which holds the shutter plate; and a detector that detects a displacement of the shutter plate held by the arm from a holding reference position, the method comprising: measuring a distance between the detector and the shutter plate at least one position; and detecting a displacement of a position where the shutter plate is held.

### Advantage of the Invention

According to the vacuum film-forming apparatus of the aspect of the present invention, such laser light is irradiated from the detector at a time of detecting the position of the shutter plate. The irradiated laser light reaches the shutter plate via the window of the chamber. Then, the irradiated laser light is reflected on the surface of the shutter plate and is re-incident to the detector. The detector detects a time to the incidence of the reflected light from the emission of the laser light.

For example, when the shutter plate is displaced by such a reciprocating motion and the end portion thereof is deviated from the guide pin, the shutter plate is tilted with respect to the horizontal direction. If the laser light is emitted from the detector in this state, the time to the re-incidence of the laser light to the detector expands. The detector can reliably detect that the shutter plate is displaced to the position deviated from the guide pin by referring in advance to the time when the shutter plate is in the holding reference position and comparing it with the time in measuring.

In addition, by performing such positional displacement detection of the shutter plate from the exterior portion of the chamber via such an observation window, it is possible to easily and reliably detect from the ordinary pressure exterior portion without adding a peculiar configuration corresponding to such a vacuum environment to the detector.

In addition, according to the position detection method for the shutter plate of the vacuum film-forming apparatus of the aspect of the present invention, by measuring the distance between the detector and the shutter plate at least one or more positions and detecting the displacement of the position where the shutter plate is held, the positional displacement direction of the shutter plate can be easily detected and the displacement amount can be also detected with high precision.

### BRIEF DESCRIPTION OF THE DRAWINGS

FIG. 1 is a side sectional view showing the vacuum film-forming apparatus of the present invention.

FIG. 2 is a horizontal sectional view showing the vacuum film-forming apparatus of the present invention.

FIG. 3 is a main part sectional enlarged view showing an operation of the vacuum film-forming apparatus of the present invention.

FIG. 4 is a sectional view showing another embodiment of the vacuum film-forming apparatus of the present invention.

FIG. 5 is a plan view showing the other embodiment of the vacuum film-forming apparatus of the present invention.

FIG. 6 is a main part perspective view showing the other embodiment of the vacuum film-forming apparatus of the present invention.

FIG. 7 is a sectional view showing the other embodiment of the vacuum film-forming apparatus of the present invention.

FIG. 8 is a plan view showing the other embodiment of the vacuum film-forming apparatus of the present invention.

### DESCRIPTION OF THE EMBODIMENTS

Hereinafter, a vacuum film-forming apparatus according to the present invention will be explained based on the drawings. Furthermore, the present embodiment is an example to better understand the spirit of the invention, and unless specified otherwise, is not intended to limit the invention. Also, the drawings used in the following description in order to clarify the characteristics of the invention, for convenience, may indicate an enlarged portion of a main part and, in fact the same size and proportions of each component are not always used.

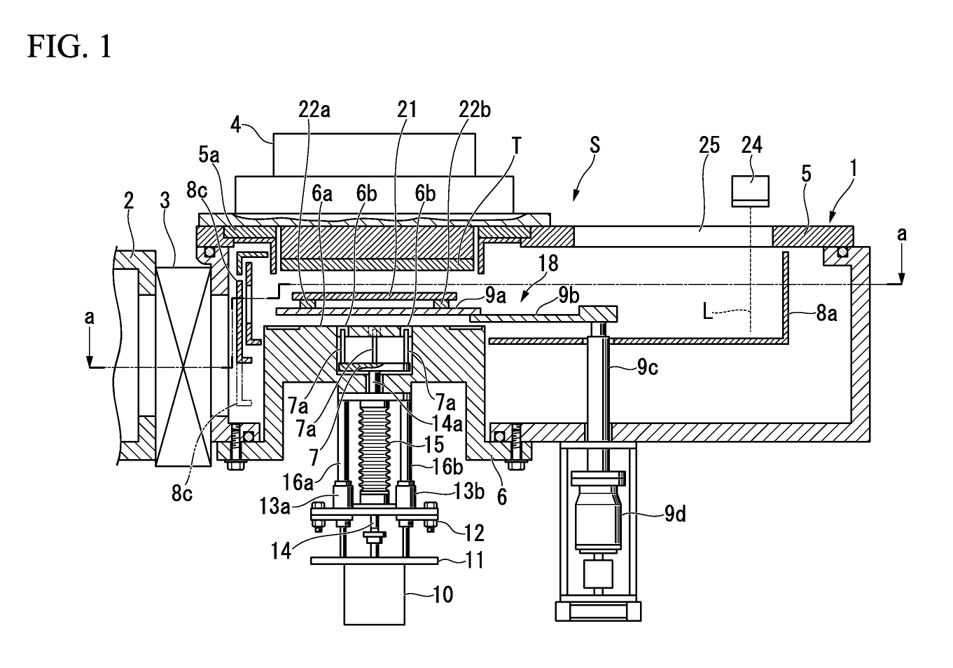

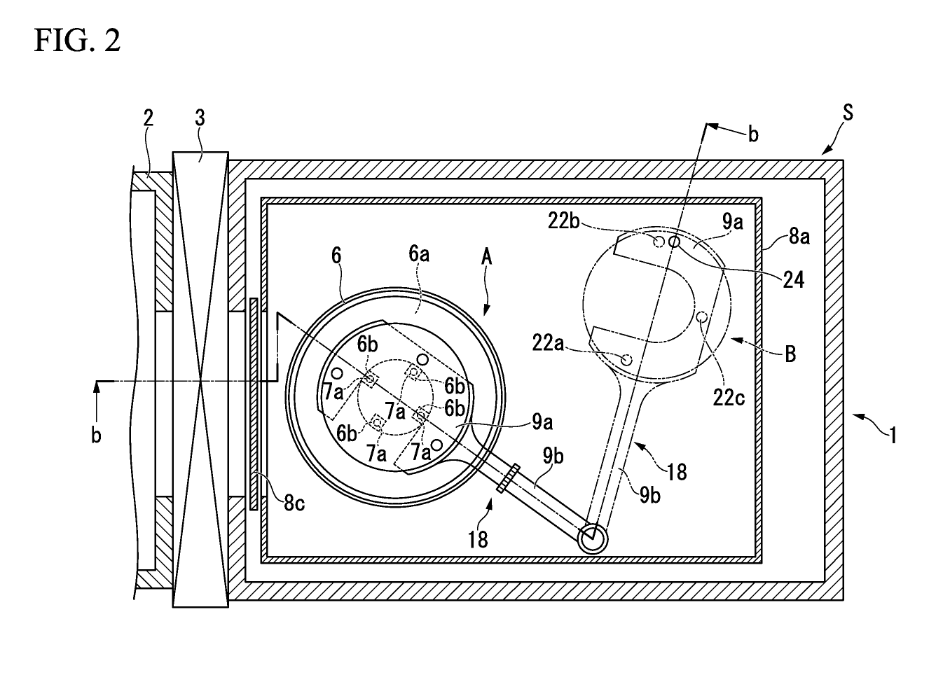

FIG. 1 is a side sectional view (in a b-b line of FIG. 2) showing a configuration example of the vacuum film-forming apparatus according to the present invention and FIG. 2 is a horizontal sectional view at an a-a line in FIG. 1. The vacuum film-forming apparatus S includes a chamber 1 that defines a film-forming chamber and is connected to a transfer chamber 2 neighboring to the left via a divider valve 3. A cathode assembly 4 is fixed to an upper portion of the chamber 1, and a target T which is a film-forming material, for example, a titanium target is fixed to a lower portion thereof. The target T has a known structure, and a holding portion thereof is mounted to an upper lid 5 via a mounting member 5a fitting into an opening of the upper lid 5 of the chamber.

A substrate electrode assembly 6 as an anode is fixed to a bottom wall portion of the film-forming chamber 1 to face to the target T at a predetermined distance inside of the film-forming chamber 1. The substrate electrode assembly 6, for example, is a round shape and a stage 6a is integrally formed to protrude in a center portion thereof. Further, for example, four through-holes 6b extending in the vertical direction are formed in the center portion of the stage 6a and four support rods 7a are formed to allow the up-and-down motion to insert into the holes, respectively.

These support rods 7a are embedded on an upper surface of a circular plate 7 at a lower end portion thereof. A center portion in a lower surface of the circular plate 7 is fixed to a drive shaft 14a, which is inserted into a vacuum bellows 15 downward, and is connected to the drive shaft 14 of a vertical drive actuator 10. A drive portion mounting plate 11 is integrally fixed in an upper surface of the actuator 10 and lower portions of shafts 16a, 16b are fixed thereto.

In upper portions of the shafts 16a, 16b, a pair of shaft direction guide members 13a, 13b fixed to a guide mounting plate 12 provided in parallel with and above the mounting plate 11 is inserted to slide. Thus, the guide mounting plate 12 is accurately movable in the vertical direction. That is, a moving force in the vertical direction of the drive shaft 14 of the actuator 10 is accurately conveyed as a moving force in the vertical direction of the support rod 7a being in an upper portion thereof.

In addition, a box-shaped wear-proof member 8a that has a cutout in a portion opposed to a divider valve 3 of which the planar shape is rectangular is formed inside of the film-forming chamber 1. In addition, a plate-like wear-proof member 8c that covers the cutout portion of the wear-proof member 8a is provided inside of the film-forming chamber 1.

The one side wear-proof member 8c moves up-and-down as shown by the dashed line and when it is in a position shown by the solid line, the film-forming is performed. In addition, when the substrate for the film-forming is carried into the film-forming chamber 1 from the transfer chamber 2 and the substrate where the film-forming has been performed is discharged to the transfer chamber 2, the wear-proof member 8c moves to the lower position shown by the dashed line.

In such the vacuum film-forming apparatus S, a prior sputtering, a so-called dummy sputtering, is performed before performing the film-forming with respect to the objective substrate for cleaning the surface of the target T, or the like. At the time of the dummy sputtering, a shutter mechanism 18 that covers the surface (the upper surface) of the stage 6a against the target T and prevents from forming the thin film on the stage 6a is provided.

The shutter mechanism 18 includes a shutter plate 21 that covers the stage 6a against the target T and an arm 9b where a shutter plate holding portion 9a that holds the shutter plate 21 on one side surface thereof is formed. In addition, the shutter mechanism 18 includes a drive shaft 9c vertically fixed to the lower end portion of the arm 9b and an actuator 9d that drives the drive shaft 9c. Furthermore, a plurality of guide pins 22a to 22c that support the shutter plate 21 from the rear surface side thereof are formed in the shutter plate holding portion 9a.

In FIG. 1, FIG. 2, the position shown by the solid line is a first position (a stage hiding position) A where the shutter plate 21 covers the stage 6a. In addition, when a sputtering (the film-forming) as a main process is performed after the dummy sputtering is completed, the shutter plate 21 moves to a second position (an evacuation position) B shown by the dashed line in FIG. 2. Further, a known valve, a gas inlet port, an exhaust system, or the like (not shown) are connected to the film-forming chamber 1.

A detecting device (a detecting apparatus, a detector) 24 that detects the displacement from the reference position of holding the shutter plate 21 is formed in the exterior portion of the chamber 1 facing to the second position (the evacuation position) B of the shutter mechanism 18. For example, the detecting device 24 may be an optical sensor unit (a laser light irradiation detection unit) that irradiates laser light toward the shutter plate 21 via a transparent window 25 formed in the upper lid 5 and receives reflected light thereof. In addition, the light spot diameter of the laser light is preferably a comparatively small diameter, for example, it may be less than 3 mm. Thus, the high precision detection can be performed. Operations of such the detecting device 24 are detailed later.

Next, an outline of the dummy sputtering performed before entering the main process of sputtering will be described. The dummy sputtering is performed for cleaning the surface of the target (for example, titanium plate) T mounted in the cathode assembly 4 and suppressing TiN film separation. When performing the dummy sputtering, argon is introduced to the inside of the chamber 1 from the gas inlet port (not shown). In addition, the arm 9b of the shutter mechanism 18 moves to the first position (the stage hiding position) A. Then, a voltage is applied to the cathode assembly 4 from a high-frequency wave or a DC power source (not shown).

Due to the known sputtering phenomena, atoms of titanium are shot from the target T, the thin film made of titanium is formed on the shutter plate 21 placed in the first position (the stage hiding position) A and titanium adheres as the thin film on also an inner peripheral surface and a bottom wall surface of the wear-proof member 8a arranged in the circumference thereof.

In this way, by performing the dummy sputtering after inserting the shutter plate 21 between the target T and the stage 6a, it is possible to prevent from forming the thin film of titanium on the stage 6a coated by the shutter plate 21 held by the shutter plate holding portion 9a. As the above process, the so-called dummy sputtering is performed and the surface of the target T is cleaned.

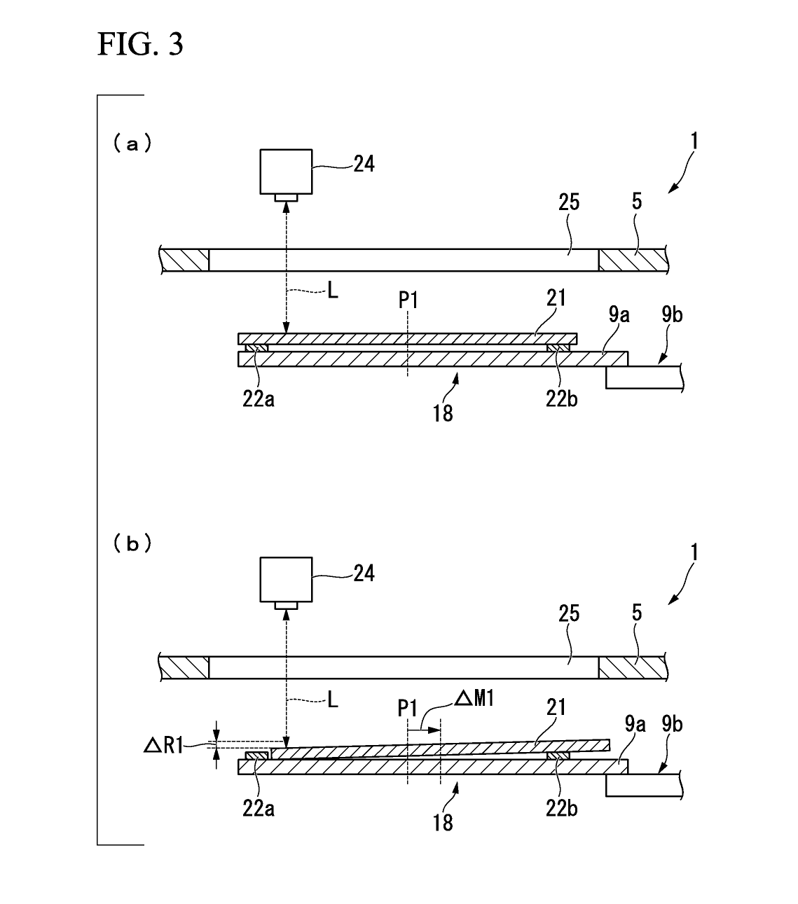

FIG. 3 is a side sectional view showing the shutter mechanism and the detecting device which are in the second position (the evacuation position) in the vacuum film-forming apparatus. For example, when the arm 9b which has the shutter plate holding portion 9a is in the second position (the evacuation position), the detecting device (the optical sensor) 24 detects whether or not the shutter plate 21 held by the shutter plate holding portion 9a is in a predetermined holding reference position (a home position) P1 with respect to the shutter plate holding portion 9a.

At a time of detecting the position of the shutter plate 21, as shown in part (a) of FIG. 3, such as the laser light L is irradiated from the detecting device (the optical sensor) 24. The irradiated laser light L reaches the shutter plate 21 via the window 25 of the chamber 1, then, is reflected on the surface of the shutter plate 21 and is incident to the detecting device 24 again. The detecting device 24 detects the time from the emission of the laser light L up to the incidence of the reflected light.

For example, as shown in part (b) of FIG. 3, when the shutter plate 21 is displaced to the right direction as in the figure at the displacement amount ΔM1 due to such as the reciprocating motion from or to the first position (the stage hiding position) and the end portion thereof deviates from the guide pin 22a, the shutter plate 21 is inclined to the horizontal direction. In this state, if the laser light L is emitted from the detecting device 24, the time until the laser light L is re-incident to the detecting device 24 becomes twice as long as the light path difference ΔR1.

For example, there was a situation where the shutter plate 21 is delivered in a state where the arm 9b vibrates due to hardening of the motion of a bearing in a motor which drives the arm 9b and thus the shutter plate 21 is delivered while displacing from the predetermined position. In addition, there was a problem, for example, that a thrusting and raising intensity when the support rod 7a, which raises and lowers the shutter plate 21 from the stage 6a, thrusts and raises the shutter plate 21 is too high, the shutter plate 21 jumps and is displaced in the traverse direction. Furthermore, there was a problem, for example, that the shutter plate 21 supported by the support rod 7a is positionally displaced on the support rod 7a due to such as the vibration from the exterior portion.

However, in the present embodiment, the detecting device 24 can reliably detect that the shutter plate 21 is displaced to the position where it deviates from the guide pin 22a by referring in advance to the time when the shutter plate 21 is in the holding reference position (the home position) P1 and comparing it with the time in measuring.

In addition, by performing such the positional displacement detection of the shutter plate 21 via such an observation window from the exterior portion of the chamber, it is possible to easily and reliably detect from the ordinary pressure exterior portion without adding a peculiar configuration corresponding to such as the vacuum environment to the detecting device 24.

Further, in the aforementioned embodiment, the detecting device 24 measures the displacement based on the reaching time of the reflection of the laser light, however, it is naturally not limited to this, and it is preferable to use a triangle ranging method based on the laser light.

In addition, in the aforementioned embodiment, the laser light is used as the detecting device 24, however, it is naturally not limited to this, for example, and the positional displacement may be detected by using the optical fiber instead of using the laser light. Furthermore, when the LED is used instead of using the laser light, it is necessary to squeeze the light spot diameter by a convex lens.

In the present embodiment, the displacement of the shutter plate 21 in a direction (a planar direction of the shutter plate 21) which intersects the thickness direction of the shutter plate 21 is detected based on the detected result of the distance to the shutter plate 21 in a detection shaft direction (a light shaft direction, an irradiation direction, a detection direction) of the detecting device 24. That is, at least the presence or absence of the displacement of the shutter plate 21 is detected based on the comparison result between the detected distance and a predetermined reference value. In the present embodiment, the shutter plate holding portion 9a has a configuration where the posture of the shutter plate 21 changes due to the displacement of the shutter plate 21. The detecting device 24 detects the change of the posture of the shutter plate 21 (a gradient change) due to the displacement of the shutter plate 21 in the traverse direction (horizontal direction). In another embodiment, the detecting device 24 may detect the change of the surface height position of the shutter plate 21 in a predetermined detection position (horizontal position) due to the displacement of the shutter plate 21 in the traverse direction (horizontal direction).

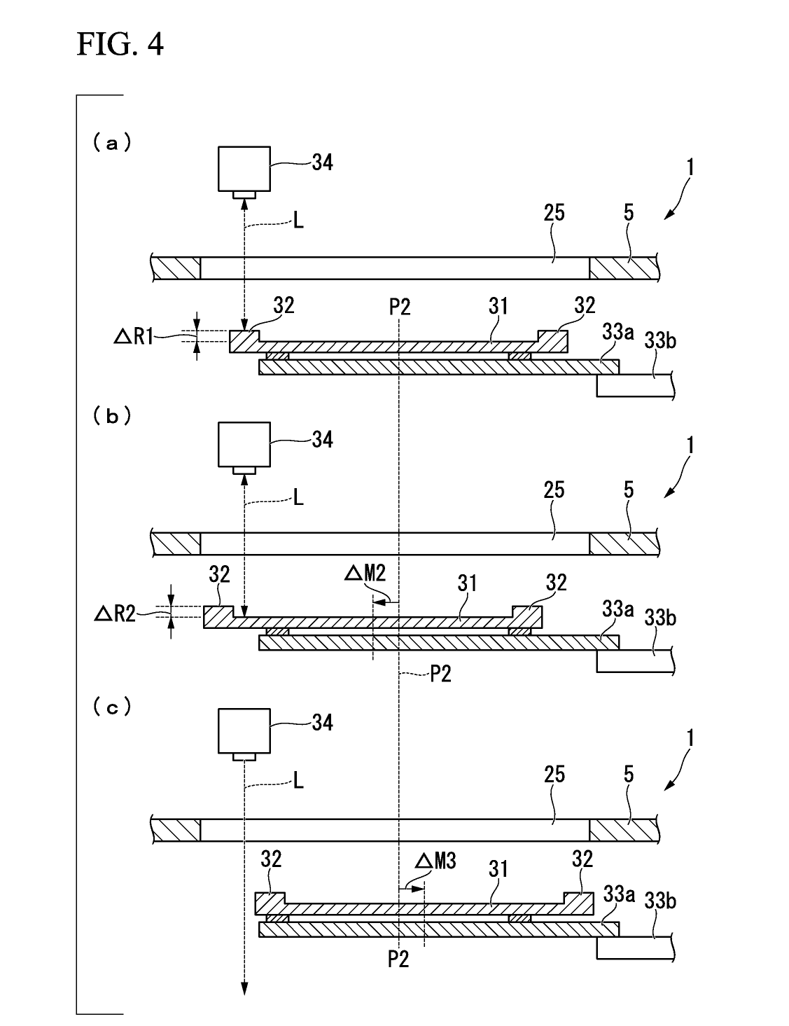

FIG. 4 is a side sectional view showing the other embodiment of the shutter mechanism in the vacuum film-forming apparatus according to the present invention. As shown in part (a) of FIG. 4, the shutter plate 31 in this embodiment has two or more sites where the thicknesses thereof are different from each other. For example, a flange portion 32 is formed where the thickness in the outer edge portion of the shutter plate 31 is thicker than that in the center portion thereof.

When an arm 33b which has a shutter plate holding portion 33a where the shutter plate 31 formed in such the feature is placed is in the second position (the evacuation position) and the shutter plate 31 is in the holding reference position (the home position) P2, an irradiation position of the laser light L irradiated from the detecting device 34, namely a measurement position, is set to the position in the flange portion 32 of the shutter plate 31.

Then if the shutter plate 31 is displaced at the displacement amount ΔM2 to, for example, the left direction as shown in part (b) of FIG. 4 due to the reciprocating motion from or to the first position (the stage hiding position), the irradiation position of the laser light L irradiated from the detecting device 34, namely the measurement position, is the position which deviates from the flange portion 32 of the shutter plate 31.

Thus, even if the shutter plate 31 does not displace to the position which deviates from the guide pin 35a and the guide pin 35b, namely, even if the displacement amount of the shutter plate 31 is so as not to incline from the horizontal surface, the time until the laser light L emitted from the detecting device 34 is re-incident to the detecting device 24 becomes twice as long as a light path difference ΔR2 corresponding to the thickness of the flange portion 32.

Then, the detecting device 34 can reliably and with high precision detect the displacement of the shutter plate 31 from the holding reference position (the home position) P2 by referring in advance to the time when the shutter plate 21 is in the holding reference position (the home position) P2 and comparing it with the time in measuring.

Meanwhile if the shutter plate 31 is displaced at a displacement amount ΔM3 to, for example, the right direction as shown in part (c) of FIG. 4 due to such as the reciprocating motion from or to the first position (the stage hiding position), the irradiation position of the laser light L irradiated from the detecting device 34, namely the measurement position, is the position which deviates from the end portion of the shutter plate 31 itself.

Therefore, since the laser light L irradiated from the detecting device 34 is not reflected on the shutter plate 31, the detecting device 34 cannot detect the reflected light. Thus, even if the shutter plate 31 does not displace to the position which deviates from the guide pin 35a and the guide pin 35b, the displacement of the shutter plate 31 from the holding reference position (the home position) P2 can be reliably detected with high precision.

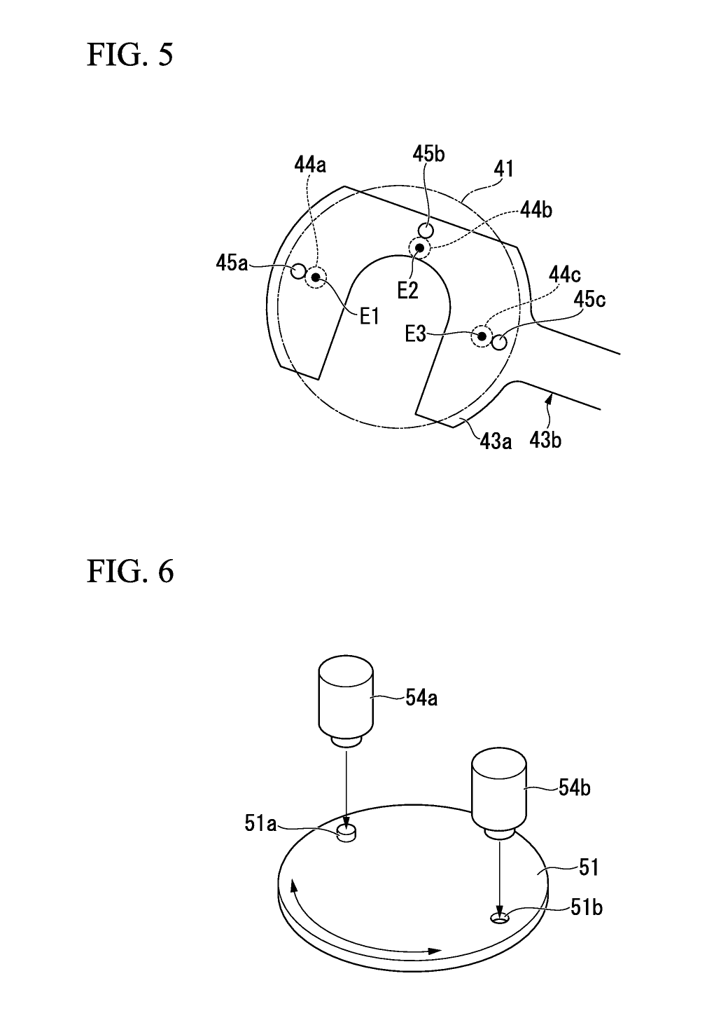

It is preferable that the detecting devices that detect the displacement of the shutter plate be provided in plural positions. For example, in the embodiment as shown in FIG. 5, the guide pins 45a to 45c that support the shutter plate 41 are formed in the shutter plate holding portion 43a that configures the arm 43b. In addition, the detecting devices 44a to 44c are formed so that the positions close to each of the guide pins 45a to 45c become the irradiation positions of the laser lights, namely the measurement positions E1, E2, E3.

In this way, the displacement direction of the shutter plate 41 can be accurately comprehended by performing the detection at the plurality of the positions in the shutter plate 41 by using a plurality of the detecting devices 44a to 44c. In addition, the displacement of the laser light detected by the detecting devices 44a to 44c may be increased by arranging the detecting devices 44a to 44c close to the guide pins 45a to 45c thus even if the displacement amount of the shutter plate 41 is small, the displacement of the shutter plate 41 may be detected with high precision.

It is also preferable that a concave and/or a convex be formed on the shutter plate so that the detection precision increases. For example, in the embodiment as shown in FIG. 6, a convex portion 51a and a concave portion 51b are formed on one side surface of the shutter plate 51. The detecting devices 54a, 54b are formed so that such the convex portion 51a and the concave portion 51b becomes the irradiation position of the laser light, namely the measurement position.

The light path difference of the laser light when the shutter plate 51 moves to the position which deviates from the convex portion 51a or the concave portion 51b can be increased by forming the convex portion 51a and/or the concave portion 51b on the shutter plate 51, the detecting devices 54a, 54b can detect the small positional displacement of the shutter plate 51 with high precision.

Further, if a groove and/or a protrusion that engage to such the convex portion 51a and/or the concave portion 51b are formed on the arm side so that the shutter plate 51 is prevented from rotating, the positional displacement detection precision of the shutter plate 51 can be furthermore increase.

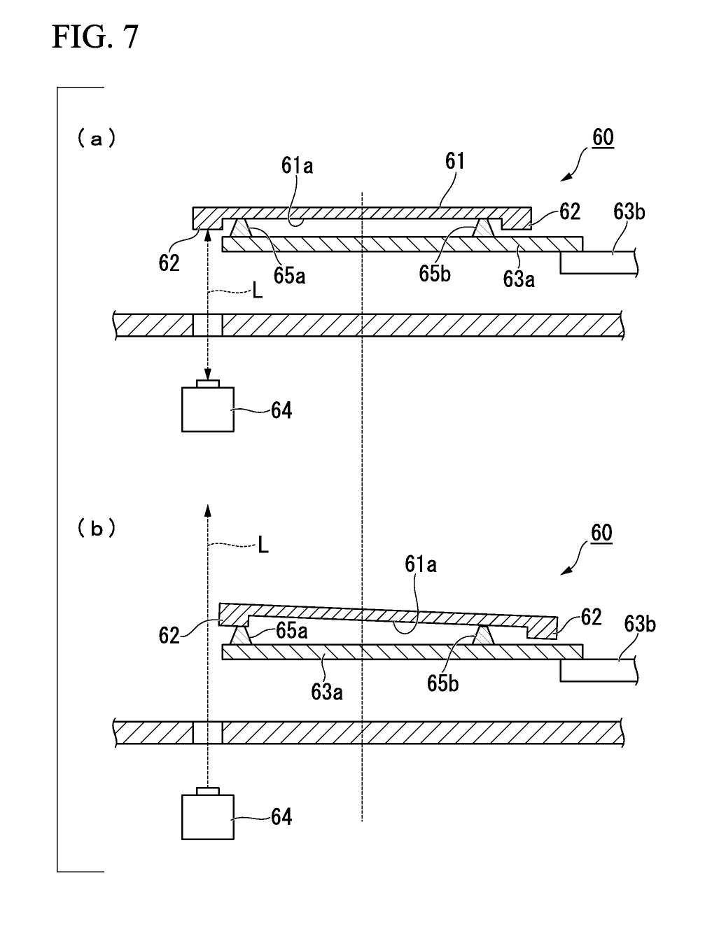

FIG. 7 is a side sectional view showing the other embodiment of the shutter mechanism in the vacuum film-forming apparatus according to the present invention. As shown in part (a) of FIG. 7, the shutter plate 61 that configures the vacuum film-forming apparatus 60 in this embodiment has two or more sites where the thicknesses thereof are different from each other. For example, the flange portion 62 is formed where the thickness in the outer edge portion of the shutter plate 61 is thicker than that in the center portion thereof. The shutter plate 61 is arranged so that the protrusion direction of the flange portion 62 becomes the downside direction in the vertical direction, namely, the concave portion 61a which is the center portion faces to the downside direction therein. Then, the shutter plate 61 is supported so that the guide pin 65a and the guide pin 65b come in contact with the concave portion 61a defined by the flange portion 62.

When the arm 63b that has the shutter plate holding portion 63a where the shutter plate 61 formed in such the feature is placed is in the second position (the evacuation position) and the shutter plate 61 is in the holding reference position (the home position), the irradiation position of the laser light L irradiated from the detecting device 64 arranged in the lower side in the vertical direction, namely the measurement position, is set to the position of the flange portion 62 in the shutter plate 61.

Then, for example, the shutter plate 61 is displaced to the left direction as shown in part (b) of FIG. 7 due to such as the reciprocating motion from or to the first position (the stage hiding position), the flange portion 62 rides on the guide pin 65a and the shutter plate 61 inclines from the horizontal surface, thus the irradiation position of the laser light L irradiated from the detecting device 64, namely the measurement position, is the position which deviates from the flange portion 62 of the shutter plate 61. Therefore, the displacement of the shutter plate 61 from the holding reference position (the home position) can be reliably detected with high precision.

In addition, by arranging the shutter plate 61 so that the concave portion 61a faces to the downside direction, even if such a stress that makes the shutter plate 61 displace to the traverse direction from the holding reference position (the home position) is added, a side wall of the flange portion 62 comes in contact with the guide pin 65a and the guide pin 65b, thus it is also possible to expect an effect that the displacement of the shutter plate 61 may be suppressed.

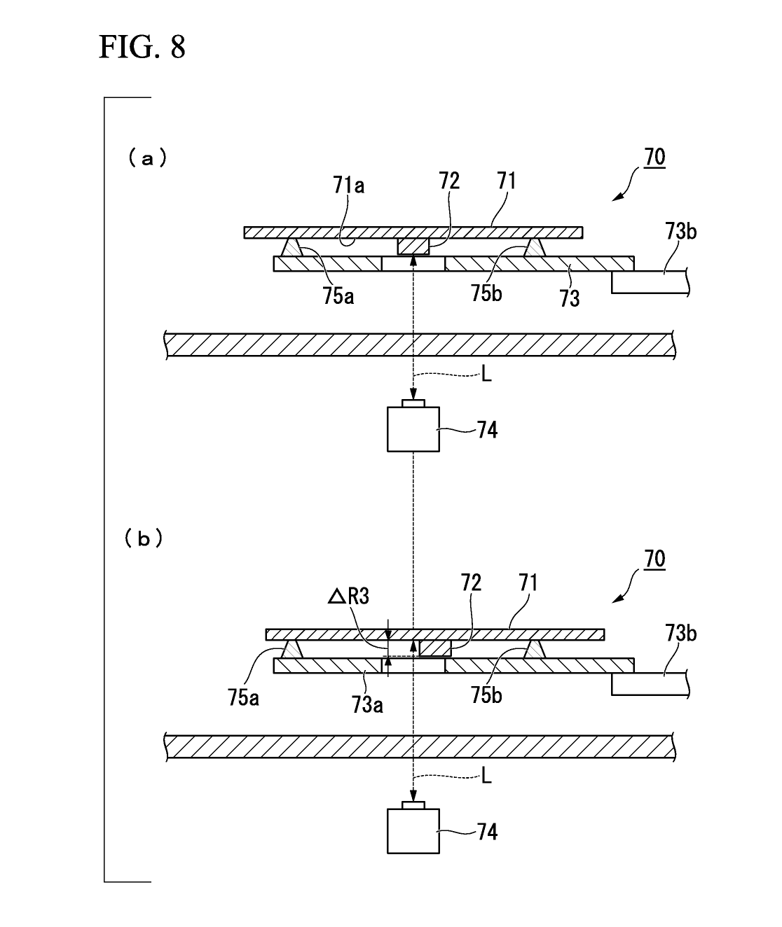

FIG. 8 is a side sectional view showing the other embodiment of the shutter mechanism in the vacuum film-forming apparatus according to the present invention. As shown in part (a) of FIG. 8, a shutter plate 71 that configures a vacuum film-forming apparatus 70 in this embodiment has two or more sites where the thicknesses thereof are different from each other. For example, the thickness of a center portion 72 in the shutter plate 71 is formed to be thicker than the thickness of the peripheral portion thereof. The shutter plate 71 is arranged so that the protrusion direction of the center portion 72 becomes the downside direction in the vertical direction.

When the arm 73b that has the shutter plate holding portion 73a where the shutter plate 71 formed in such the feature is placed is in the second position (the evacuation position) and the shutter plate 71 is in the holding reference position (the home position), the irradiation position of the laser light L irradiated from the detecting device 74 arranged in the lower side in the vertical direction, namely the measurement position, is set to the position of the center portion 72 of the shutter plate 71.

Then if the shutter plate 71 is displaced to, for example, the left direction as shown in part (b) of FIG. 8 due to such as the reciprocating motion from or to the first position (the stage hiding position), the irradiation position of the laser light L irradiated from the detecting device 74, namely the measurement position, is the position which deviates from the center portion 72 of the shutter plate 71. Therefore, the displacement of the shutter plate 71 from the holding reference position (the home position) can be reliably detected with high precision.

Furthermore, the present embodiment in order to better understand the spirit of the invention is to illustrate one example cited, and unless specified otherwise, is not intended to limit the invention. For example, in the aforementioned embodiment, the thickness of the center portion 72 of the shutter plate 71 is formed to be thicker than the thickness of the peripheral portion and the protrusion direction of the center portion 72 is arranged to face to the downside direction in the vertical direction, however, instead of this, the thickness of the center portion of the shutter plate may be formed to be thinner than the thickness of the peripheral portion, and furthermore, an annular groove may be formed along the center portion of the shutter plate.

### DESCRIPTION OF THE REFERENCE SYMBOLS

1 . . . Chamber
6a . . . Stage
9b . . . Arm
21 . . . Shutter plate
18 . . . Shutter Mechanism
24 . . . Detecting Device
T . . . Target
S . . . Vacuum Film-Forming Apparatus

What is claimed is:

1. A vacuum film-forming apparatus comprising:
a chamber that maintains a vacuum of an inside thereof;
a stage that is formed in the chamber and on which a shutter plate is placed;
a target that is arranged so as to be opposed to the stage;
a shutter mechanism that is formed so as to be capable of inserting into and evacuating from a space between the stage and the target and that has an arm which holds the shutter plate; and
a detector that detects a displacement of the shutter plate held by the arm from a holding reference position.

2. The vacuum film-forming apparatus according to claim 1, wherein the detector is an optical sensor that detects a reflected light which is light irradiating toward the shutter plate and reflected by the shutter plate.

3. The vacuum film-forming apparatus according to claim 1, wherein the detector is an optical sensor that detects an intensity distribution of the reflected light with a solid-state image sensing device.

4. The vacuum film-forming apparatus according to claim 1, wherein the detector is arranged in an exterior of the chamber.

5. The vacuum film-forming apparatus according to claim 1, wherein the detector is arranged close to a guide pin which is formed in the arm and comes in contact with and supports the shutter plate.

6. The vacuum film-forming apparatus according to claim 1, wherein the shutter plate has two or more sites where thicknesses thereof are different from each other.

7. The vacuum film-forming apparatus according to claim 1, wherein a thickness of an outer edge portion of the shutter plate is thicker than that of a center portion thereof.

8. A position detection method for a shutter plate of a vacuum film-forming apparatus comprising:
a chamber that maintains a vacuum of an inside thereof;
a stage that is formed in the chamber and on which a shutter plate is placed;
a target that is arranged so as to be opposed to the stage;
a shutter mechanism that is formed so as to be capable of inserting into and evacuating from a space between the stage and the target and that has an arm which holds the shutter plate; and
a detector that detects a displacement of the shutter plate held by the arm from a holding reference position, the method comprising:
measuring a distance between the detector and the shutter plate at least one position; and
detecting a displacement of a position where the shutter plate is held.
